(19) United States
(12) Patent Application Publication
(10) Pub. No.: US 2026/0292966 A1
(43) Pub. Date: Sep. 24, 2026

(54) ELECTRONIC DEVICE AND METHOD OF MANUFACTURING THE SAME

(71) Applicant: Advanced Semiconductor Engineering, Inc., Kaohsiung (TW)

(72) Inventors: Po-Ming LEE, Kaohsiung (TW); Erh-Ju LIN, Kaohsiung (TW); Lu-Ming LAI, Kaohsiung (TW)

(73) Assignee: Advanced Semiconductor Engineering, Inc., Kaohsiung (TW)

(21) Appl. No.: 19/438,527

(22) Filed: Dec. 31, 2025

Related U.S. Application Data
(60) Provisional application No. 63/775,993, filed on Mar. 21, 2025.

(51) Int. Cl. H05K 1/02; H05K 1/181

(52) U.S. Cl. CPC H05K 1/0203; H05K 1/181

(57) ABSTRACT

An electronic device and method of manufacturing the same are provided. The electronic device includes a carrier and an electronic component. The carrier includes a first conductive layer, wherein the first conductive layer includes a non-nanotwin copper layer and has an average grain size equal to or less than about 150 nm. The electronic component includes a pad electrically connected to the first conductive layer. The pad of the electronic component and the first conductive layer define a copper-to-copper bond.

### CROSS-REFERENCE TO RELATED APPLICATIONS

This application claims the benefit of U.S. Provisional Application No. 63/775,993, filed Mar. 21, 2025, the entire disclosure of which is incorporated by reference herein.

### BACKGROUND

### 1. Technical Field

The present disclosure relates generally to an electronic device. Specifically, the present disclosure relates to an electronic device including a conductive layer of ultra-fine grain(s).

### 2. Description of the Related Art

Currently, metal-to-metal interfaces (e.g., copper-to-copper) face several challenges, including the formation of Kirkendall voids, pad consumption, contamination by impurities, intermetallic compound (IMC) formation, sidewall wetting at the Cu pillar, low thermal conductivity, thermal management issues, and other related problems. These factors can result in short circuits and decreased manufacturing yields.

### SUMMARY

In some embodiments, an electronic device includes a carrier and an electronic component. The carrier includes a first conductive layer, wherein the first conductive layer includes a non-nanotwin copper layer and has an average grain size equal to or less than about 150 nm. The electronic component includes a pad electrically connected to the first conductive layer. The pad of the electronic component and the first conductive layer define a copper-to-copper bond.

In some embodiments, an electronic device includes a carrier, an electronic component, a first ultra-fine grain copper (UFG-Cu) layer, and a heat dissipating structure. The electronic component is disposed on the carrier. The electronic component has a first surface facing the carrier and a second surface opposite to the first surface, The first UFG-Cu layer is disposed over the second surface of the electronic component. The heat dissipating structure is disposed on the first UFG-Cu layer.

In some embodiments, a method of manufacturing an electronic device includes: providing a first carrier having a first pad; forming a first ultra-fine grain copper (UFG-Cu) layer over the pad of the first carrier, wherein an average grain size of the first UFG-Cu layer is equal to or less than about 150 nm; providing a component having a second pad; and bonding the second pad and the first UFG-Cu layer.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIGS. 1A and 1B illustrate stages of an example of a method for manufacturing an electronic device in accordance with some arrangements of the present disclosure.

FIGS. 2A and 2B illustrate stages of an example of a method for manufacturing an electronic device in accordance with some arrangements of the present disclosure.

FIGS. 3A and 3B illustrate stages of an example of a method for manufacturing an electronic device in accordance with some arrangements of the present disclosure.

FIGS. 4A and 4B illustrate stages of an example of a method for manufacturing an electronic device in accordance with some arrangements of the present disclosure.

FIGS. 5A and 5B illustrate stages of an example of a method for manufacturing an electronic device in accordance with some arrangements of the present disclosure.

FIG. 6 is a cross-section of an electronic device in accordance with some arrangements of the present disclosure.

FIG. 7 is a cross-section of an electronic device in accordance with some arrangements of the present disclosure.

FIG. 8 is a cross-section of an electronic device in accordance with some arrangements of the present disclosure.

FIG. 9A is a cross-section of a bonding structure in accordance with some arrangements of the present disclosure.

FIG. 9B illustrates a microstructure of the bonding structure as shown in FIG. 9A, in accordance with some arrangements of the present disclosure.

FIG. 10A is a cross-section of a bonding structure in accordance with some arrangements of the present disclosure.

FIG. 10B illustrates a microstructure of the bonding structure as shown in FIG. 10A, i accordance with some arrangements of the present disclosure.

FIG. 11A is a cross-section of a bonding structure in accordance with some arrangements of the present disclosure.

FIG. 11B is an enlarged view of the electronic device as shown in FIG. 11A, in accordance with some arrangements of the present disclosure.

FIGS. 12 and 13 illustrate partial microstructures at various stages of manufacturing an electronic device, in accordance with some arrangements of the present disclosure.

FIGS. 14 and 15 illustrate partial microstructures at various stages of manufacturing an electronic device, in accordance with some arrangements of the present disclosure.

FIG. 16 illustrates a partial microstructure of the electronic device as shown in FIG. 4B, in accordance with some arrangements of the present disclosure.

FIGS. 17, 18, and 19 illustrate partial microstructures at various stages of manufacturing an electronic device, in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

The present disclosure provides an electronic device including copper-to-metal bonding (e.g., copper-to-copper bonding, copper-to-gold bonding, or the like). The copper layer features ultra-fine grains (UFGs) with a grain size equal to 300 nm, 150 nm, 100 nm, 50 nm, or less. This ultra-fine-grained copper layer may simplify the processing conditions and/or steps. For instance, the copper-to-copper bonding of UFG copper can be achieved at relatively low pressures (e.g., 3 MPa, 1 MPa, 0.5 MPa, 0.2 MPa, 0.1 MPa, or lower) and temperatures (e.g., below 200° C., 180° C., 170° C., 160° C., 150° C., 130° C., 120° C., or lower). The copper layer with UFGs may exhibit a significantly lower surface roughness (e.g., the surface roughness (Ra) less than about 0.5 nm) compared to a regular copper layer. In certain instances, a planarization process, such as chemical mechanical planarization, may be omitted. In some cases, this UFG-Cu layer can serve as a conductive planarization layer, which may be formed on other metallic materials (e.g., gold, silver, nickel, titanium, alloys, or other materials) or on a regular copper layer that has a relatively large grain size, effectively reducing the surface roughness of a metal surface. For example, the UFG-Cu layer may be formed on or bonded to the surface(s) of a lead frame, a pad, a heat dissipating structure, or other metallic layers. In some arrangements, the UFG-Cu layer can be bonded to other metallic materials, such as gold, nickel, titanium, silver, aluminum, an alloy, or other suitable materials.

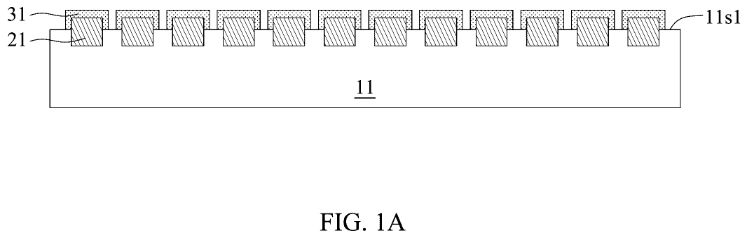

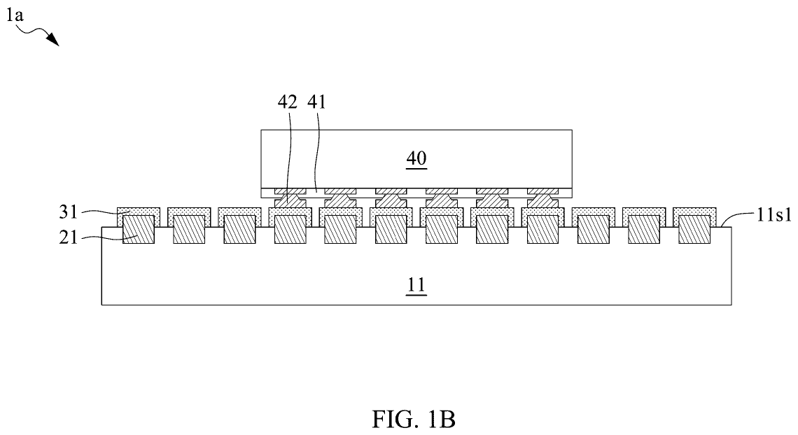

FIGS. 1A and 1B illustrate stages of an example of a method for manufacturing an electronic device 1a in accordance with some arrangements of the present disclosure.

Referring to FIG. 1A, a carrier 11 may be provided. In some arrangements, the carrier 11 may include a semiconductor substrate, such as silicon, germanium, and other group III-V and group IV materials. The carrier 11 may include metal lines and vias, including but not limited to through-silicon vias (TSVs) for interconnection. A dielectric material, such as polyimide, silicon oxide, or other suitable materials, may be formed on the semiconductor substrate. In some arrangements, the carrier 11 may be formed as a printed circuit board (PCB), flexible printed circuit board (FPCB), or other suitable circuit structures. In some arrangements, the carrier 11 may include a lead frame, which may include a patterned trace on its exposed surfaces for electrical connection. The carrier 11 may have a surface 11s1, which may function as an active surface for signal or power transmission. The carrier 11 may include a panel, a wafer, or other suitable supporters.

A conductive layer 21 may be formed on the surface 11s1. The conductive layer 21 may abut the surface 11s1. In some arrangements, the conductive layer 21 may include a conductive material. For example, the conductive layer 21 may include copper, gold, silver, nickel, titanium, alloys, or other materials. In some arrangements, the conductive layer 21 may be formed on the surface 11s1 by, for example, electroplating, electroless plating, or other suitable techniques. In some arrangements, the conductive layer 21 may be partially embedded within the carrier 11. In some arrangements, the conductive layer 21 may be partially protruded from the surface 11s1 of the carrier 11.

In some arrangements, the conductive layer 21 may include or be made of copper. In some arrangements, the conductive layer 21 may include a nanotwin (or nanotwinned) copper (NT-Cu) structure. In some arrangements, the term “nanotwin” may refer to two grains (or two portions of a crystal) that are formed mirrored across a common crystallographic plane. In some arrangements, the term “nanotwin” may refer to two grains forming a nanotwin boundary (or twin boundary) between them. The nanotwin crystal structure may include a plurality of grains each including a plurality of nanotwin crystals (or “nanotwins”, “nanotwin layers”, or “multi-layers”) stacked along the common crystallographic plane. In some arrangements, the NT-Cu structure may have a [111] crystallographic plane. In some arrangements, the NT-Cu structure may be highly oriented, suggesting that exceeding 85%, 90%, 95%, 98%, or 99% of grains within the NT-Cu structure possess a [111] crystallographic plane.

In some arrangements, the conductive layer 21 may include a non-NT-Cu structure. In some arrangements, the conductive layer 21 may include a [100] crystallographic plane(s), a [110] crystallographic plane(s), and a [111] crystallographic plane(s). In some arrangements, the grains of the non-NT-Cu structure may substantially have no twin boundaries therebetween.

In some arrangements, the NT-Cu structure may refer to a structure having NT-Cu greater than or about 85 wt. % NT-Cu, greater than or about 90 wt. % NT-Cu, greater than or about 95 wt. % NT-Cu, greater than or about 98 wt. % NT-Cu, or more. In some arrangements, the non-NT-Cu structure may refer to a structure having NT-Cu less than or about 20 wt. % NT-Cu, less than or about 15 wt. % NT-Cu, less than or about 10 wt. % NT-Cu, less than or about 5 wt. % NT-Cu, 1 wt. % NT-Cu, or less.

In some arrangements, a conductive layer 31 (or bonding layer) may be formed on the conductive layer 21. In some arrangements, the conductive layer 31 may include a conductive material, such as copper, gold, silver, nickel, titanium, alloys, or other materials. In some arrangements, the conductive layer 31 may include a non-NT-Cu structure. In some arrangements, the grain size (or average grain size or medium diameter (D50)) of the conductive layer 31 may be less than that of the conductive layer 21. In some arrangements, the conductive layer 31 may include an ultra-fine grain copper (UFG-Cu) layer. In some arrangements, the grain size (or average grain size or D50) of the conductive layer 31 may be equal to about 300 nm, 150 nm, 100 nm, 50 nm, or less. In some arrangements, the grain size of the conductive layer 21 may be greater than or equal to about 1 μm, 1.5 μm, 2 μm, or more. In some arrangements, the conductive layers 21 and 31 may define a partially continuous boundary therebetween. In some arrangements, the conductive layer 31 may be formed by, for example, electroplating, electroless plating, or other suitable techniques. In some arrangements, the process conditions for forming the conductive layer 21 may be different from those of the conductive layer 31.

Referring to FIG. 1B, an electronic component 40 may be provided. In some arrangements, the electronic component 40 may include a chip or a semiconductor die. The electronic component 40 may include a central processing unit (CPU), a microprocessor unit (MPU), a graphics processing unit (GPU), a microcontroller unit (MCU), a radio frequency integrated circuit (RFIC), an application-specific IC (ASIC), a field-programmable gate array (FPGA), high band memory (HBM) die, dynamic random access memory (DRAM) die, static random access memory (SRAM) die, or other integrated circuits (ICs). In some arrangements, the electronic component 40 may include a dielectric layer 41 and a conductive layer 42.

The dielectric layer 41 may be formed on the active surface of the electronic component 40. In some arrangements, the dielectric layer 41 may include oxide, nitride, polyimide, polybenzoxazole, benzocyclobuten, polypropylene, or other suitable materials.

In some arrangements, the conductive layer 42 may be formed on the active surface of the electronic component 40. In some arrangements, the conductive layer 42 may include a conductive material, such as copper, gold, silver, nickel, titanium, alloys, or other materials. In some arrangements, the conductive layer 42 may include non-NT-Cu structures. In some arrangements, the conductive layer 42 may include UFG-Cu layers. In some arrangements, the conductive layer 42 may be formed by, for example, electroplating, electroless plating, or other suitable techniques.

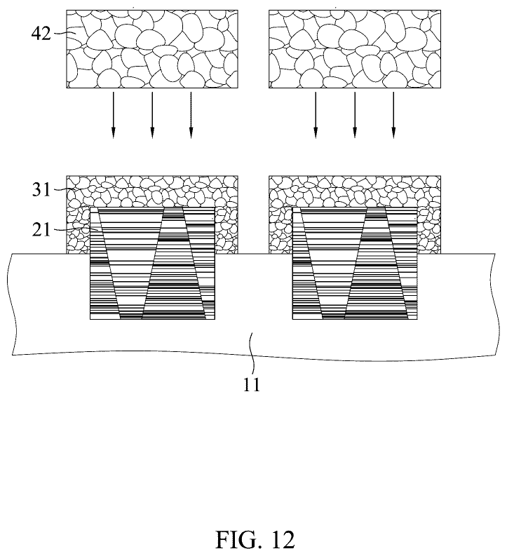

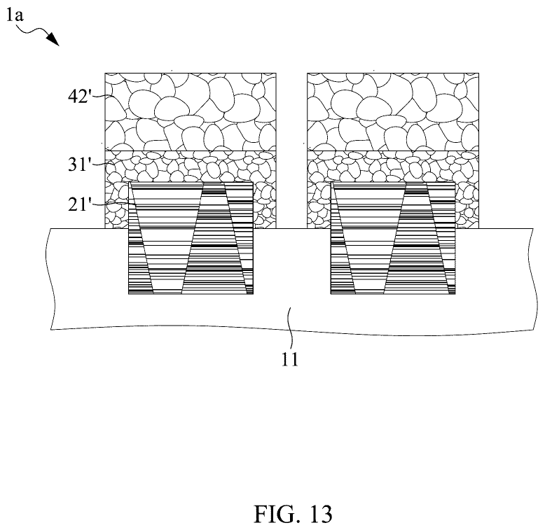

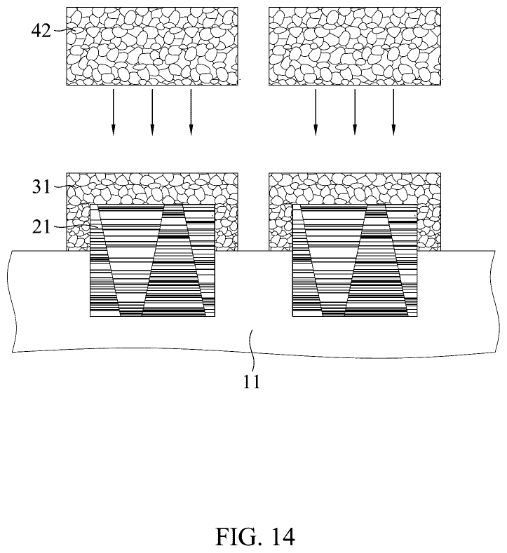

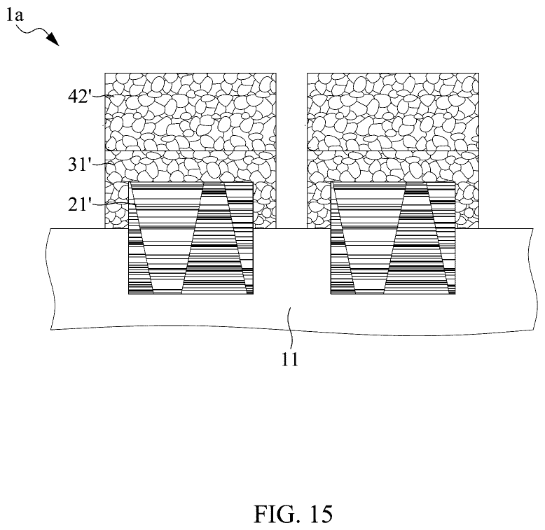

In some arrangements, the electronic component 40 may be bonded to the carrier 11. For example, the conductive layer 31 may be bonded to the conductive layer 42 by a copper-to-copper bonding technique. In some arrangements, both the conductive layers 31 and 42 include UFG-Cu layers, which may improve process windows (e.g., pressure, temperature, process time, or other parameters). In some arrangements, the conductive layer 31 may be bonded to the conductive layer 42 under a pressure less equal to 3 MPa, 1 MPa, 0.5 MPa, 0.2 MPa, 0.1 MPa or lower. In some arrangements, the conductive layer 31 may be bonded to the conductive layer 42 under a temperature equal to 200° C., 180° C., 170° C., 160° C., 150° C., 130° C., 120° C., or less. In some arrangements, the conductive layer 31 may be bonded to the conductive layer 42 within 60 minutes, 30 minutes, 15 minutes, or less. In some arrangements, no void is formed at the interface between the conductive layers 31 and 42. Further, the change in grain size of the conductive layers 21, 31, and 42 is illustrated in FIGS. 12 and 13 (or FIGS. 14 and 15).

In a comparative example, a copper-to-copper bonding technique is employed using a copper layer with a grain size exceeding 1 μm. This process is conducted at temperatures above 200° C., under pressures greater than 5 MPa, and/or for durations exceeding 60 minutes. In contrast to this comparative example, electronic device 1a can be manufactured under improved processing conditions and reduced cycle times. In another comparative example, a heterometallic bonding technique is utilized to bond metal materials, which enhances the process window. However, this approach may lead to the formation of intermetallic compounds (IMCs), such as indium-copper or tin-copper, which can adversely affect the electrical properties and reliability of the electronic device. In this arrangement, both the conductive layers 31 and 42 include UFG-Cu layers, which prevents the formation of intermetallic compounds (IMCs) within the bonded structure of these layers.

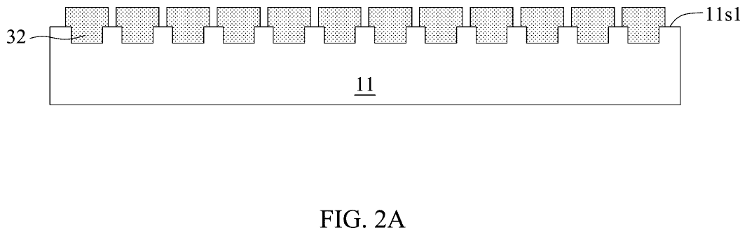

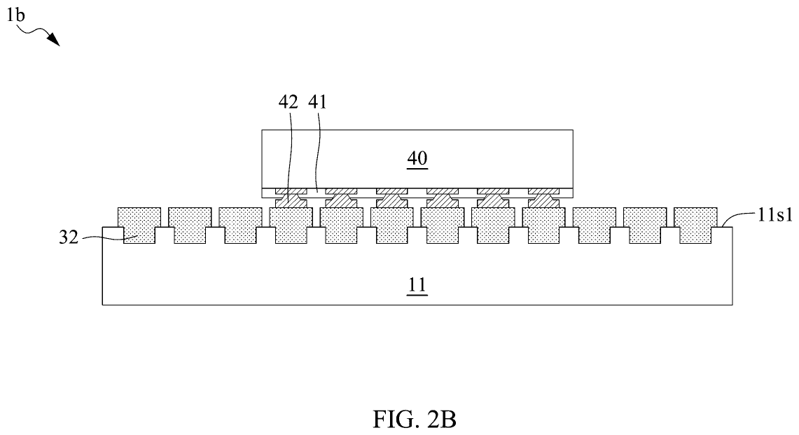

FIGS. 2A and 2B illustrate stages of an example of a method for manufacturing an electronic device 1b in accordance with some arrangements of the present disclosure.

Referring to FIG. 2A, the carrier 11 may be provided. In some arrangements, the conductive layer 21 as shown in FIG. 1A may be omitted. For example, a conductive layer 32 may be directly formed on the surface 11s1 of the carrier 11. In some arrangements, the conductive layer 32 may include a conductive material, such as copper, gold, silver, nickel, titanium, alloys, or other materials. In some arrangements, the conductive layer 32 may include a non-NT-Cu structure. In some arrangements, the conductive layer 32 may include a UFG-Cu layer. In some arrangements, the conductive layer 32 may be formed by, for example, electroplating, electroless plating, or other suitable techniques. In some arrangements, the conductive layer 32 may be partially embedded within the carrier 11. In some arrangements, the conductive layer 32 may be partially protruded from the surface 11s1 of the carrier 11.

Referring to FIG. 2B, the electronic component 40 may be provided. The electronic component 40 may be bonded to the carrier 11. In some arrangements, the conductive layer 32 may be bonded to the conductive layer 42. In some arrangements, the process conditions of bonding the conductive layer 42 to the conductive layer 32 may be similar to or the same as those used for bonding the conductive layer 42 to the conductive layer 31. In comparison with a comparative example, the electronic device 1b may be manufactured at an improved process condition and cycle time. Further, no IMCs are formed within the bonded structure of the conductive layers 32 and 42.

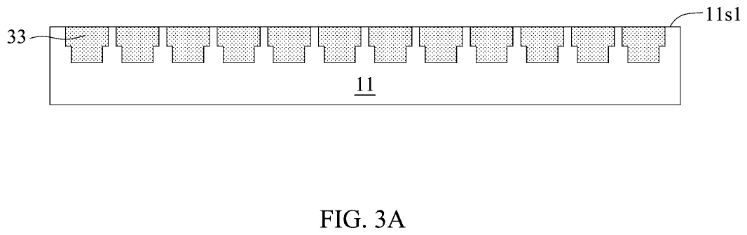

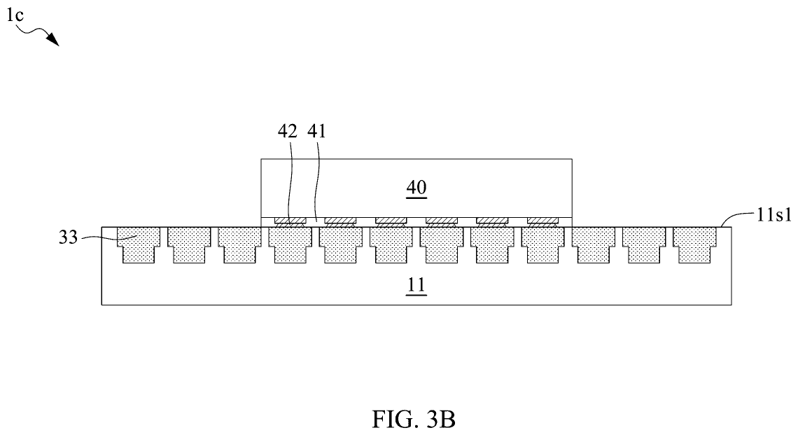

FIGS. 3A and 3B illustrate stages of an example of a method for manufacturing an electronic device 1c in accordance with some arrangements of the present disclosure.

Referring to FIG. 3A, the carrier 11 may be provided. In some arrangements, a conductive layer 33 may be embedded within the carrier 11. For example, the exposed surface of the conductive layer 33 may be substantially aligned with the surface 11s1 of the carrier 11. In some arrangements, the conductive layer 33 may include a non-NT-Cu structure. In some arrangements, the conductive layer 33 may include a UFG-Cu layer.

Referring to FIG. 3B, the electronic component 40 may be provided. The electronic component 40 may be bonded to the carrier 11. In some arrangements, the conductive layer 33 may be bonded to the conductive layer 42. In some arrangements, the process conditions of bonding the conductive layer 42 to the conductive layer 33 may be similar to or the same as those used for bonding the conductive layer 42 to the conductive layer 31. In comparison with a comparative example, the electronic device 1c may be manufactured at an improved process condition and cycle time. Further, no IMCs are formed within the bonded structure of the conductive layers 33 and 42.

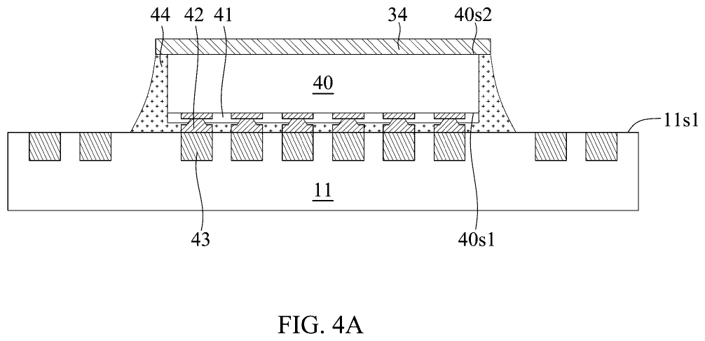

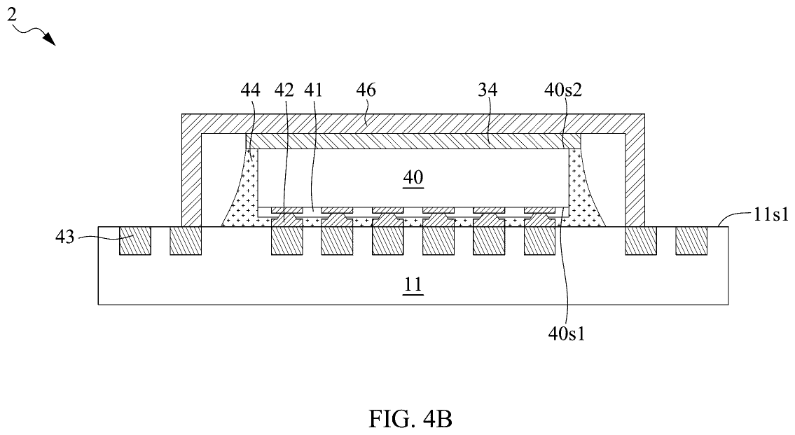

FIGS. 4A and 4B illustrate stages of an example of a method for manufacturing an electronic device 2 in accordance with some arrangements of the present disclosure.

Referring to FIG. 4A, the carrier 11 may be provided. The electronic component 40 may be provided. The electronic component 40 may have a surface 40s1 and a surface 40s2 opposite to the surface 40s1. The surface 40s1 of the electronic component 40 may face the surface 11s1 of the carrier 11. The surface 40s1 may function as an active surface, and the surface 40s2 may function as a backside surface or a passive surface. Pads 43 may be formed on the surface 11s1 of the carrier 11. The pad 43 may include a regular copper layer. The pad 43 may include gold, silver, nickel, titanium, alloys, or other materials. In some arrangements, the pad 43 may include a UFG-Cu layer. The conductive layer 42 may be bonded to the pads 43. A protection layer 44 may be formed on the carrier 11 and cover the lateral surface, which extends between the surfaces 40s1 and 40s2, of the electronic component 40. The protection layer 44 may include an underfill. In some arrangements, a conductive layer 34 may be formed on the surface 40s2 of the electronic component 40. In some arrangements, the conductive layer 34 may cover a portion of the protection layer 44. In some arrangements, the conductive layer 34 may include a conductive material, such as copper, gold, silver, nickel, titanium, alloys, or other materials. In some arrangements, the conductive layer 34 may include a non-NT-Cu structure. In some arrangements, the conductive layer 34 may include a UFG-Cu layer. In some arrangements, the conductive layer 34 may be formed by, for example, electroplating, electroless plating, or other suitable techniques. In some arrangements, the conductive layer 34 may function as a connection layer to be connected to another conductive layer, a dielectric material, or a semiconductor material. In some arrangements, FIG. 4A may illustrate a stage after additional processes are performed after the stage as shown in FIG. 1B (or FIG. 2B or 3B), the processes performed before the stage shown in FIG. 4A may be the same as or similar to those described related to FIGS. 1A and 1B (or FIGS. 2A and 2B or FIGS. 3A and 3B). For example, FIG. 4A may illustrate a structure after the protection layer 44 and the conductive layer 34 have been formed on the electronic device 1a shown in FIG. 1B. In this arrangement, the pads 43 shown in FIG. 4A may be replaced by the conductive layers 21 and 31 shown in FIG. 1B.

Referring to FIG. 4B, a heat dissipating structure 46 may be disposed over the surface 40s2 of the electronic component 40. The heat dissipating structure 46 may be thermally coupled to the carrier 11. In some arrangements, the heat dissipating structure 46 may be attached to the electronic component 40 by the conductive layer 34. In some arrangements, the heat dissipating structure 46 may be in direct contact with the conductive layer 34. In some arrangements, the heat dissipating structure 46 may be attached to the conductive layer 34 without using a conductive paste, such as silver paste or other suitable materials. In the arrangements where the pads 43 shown in FIG. 4B are replaced by the conductive layers 21 and 31, the heat dissipating structure 46 may be bonded to the conductive layer 31. In a comparative example, a conductive paste, such as silver paste, is applied between a heat dissipating structure and a backside metal layer on the passive surface of a die to enhance adhesion under relatively low pressure and temperature conditions. However, under these conditions, the conductive paste, which contains resin, may compromise thermal conductivity. To address this issue, the conductive layer 34 can be designed to attach directly to the heat dissipating structure 46 under improved processing conditions, eliminating the need for a conductive paste between the conductive layer 34 and the heat dissipating structure 46. Therefore, the electronic device 2 achieves improved thermal conductivity for heat dissipation and can be manufactured using optimized process conditions.

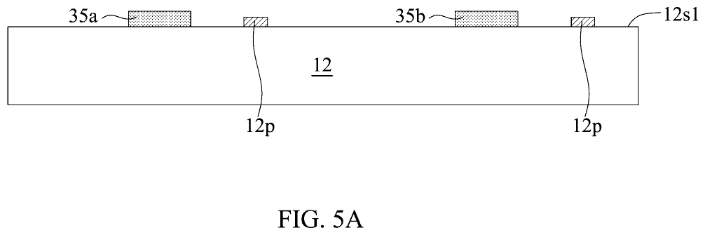

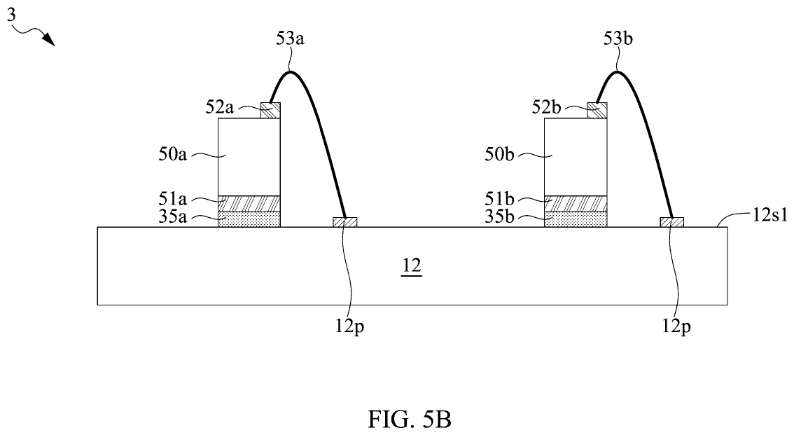

FIGS. 5A and 5B illustrate stages of an example of a method for manufacturing an electronic device 3 in accordance with some arrangements of the present disclosure.

Referring to FIG. 5A, a carrier 12 may be provided. The carrier 12 may include a semiconductor substrate, such as silicon, germanium, and other group III-V and group IV materials. In some arrangements, the carrier 12 may be formed as a PCB, FPCB, or other suitable circuit structures. In some arrangements, the carrier 12 may include a lead frame, which may include a patterned trace on its exposed surfaces for electrical connection. The carrier 12 may have a surface 12s1, which may function as an active surface for signal or power transmission. Conductive layers 35a and 35b (or pads or bonding layers) may be formed on the surface 12s1 of the carrier 12. In some arrangements, the conductive layers 35a and 35b may include a conductive material, such as copper, gold, silver, nickel, titanium, alloys, or other materials. In some arrangements, the conductive layers 35a and 35b may include a non-NT-Cu structure. In some arrangements, the conductive layers 35a and 35b may include a UFG-Cu layer. In some arrangements, the conductive layers 35a and 35b may be formed by, for example, electroplating, electroless plating, or other suitable techniques.

Referring to FIG. 5B, an optical component 50a (or electronic component) and an optical component 50b (or electronic component) may be provided. Each of the optical components 50a and 50b may include a light emitter, a light receiver, a light redirector, or other suitable components. For example, each of the optical components 50a and 50b may include a photodiode, a light-emitting diode, an organic light-emitting diode, a laser diode, or other suitable components. The optical component 50a may be optically coupled to the optical component 50b. Each of the optical components 50a and 50b may include two terminals on two opposite sides. For example, the optical component 50a may include an electrode 51a and an electrode 52a on two opposite sides of the optical component 50a. A conductive wire 53a may be electrically connected between the carrier 12 and the electrode 52a. The conductive wire 53a may be bonded to a conductive layer 12p on the surface 12s1 of the carrier 12. The conductive layer 12p may include a UFG-Cu layer. The optical component 50b may include an electrode 51b and an electrode 52b on two opposite sides of the optical component 50b. A conductive wire 53b may be electrically connected between the carrier 12 and the electrode 52b. The conductive wire 53b may be bonded to a conductive layer 12p. In some arrangements, the electrodes 51a, 51b, 52a, and 52b may include UFG-Cu layers. In some arrangements, the electrodes 51a, 51b, 52a, and 52b may include regular copper layers. In some arrangements, the electrodes 51a, 51b, 52a, and 52b may include gold, silver, nickel, titanium, alloy, or a combination thereof. For example, the electrodes 51a, 51b, 52a, and 52b may include copper, gold, or a combination thereof. Each of the conductive wires 53a and 53b may include a bonding wire, which may include copper, gold, silver, nickel, titanium, alloy, or other suitable materials. In some arrangements, the grain size of the conductive layer 12p is less than the grain size of the conductive wire 53a. In some arrangements, the grain size of the conductive layer 12p may be substantially the same as that of the conductive layer 35a.

In some arrangements, the electrode 51a may be bonded to the conductive layer 35a. In some arrangements, the electrode 51b may be bonded to the conductive layer 35b. In some arrangements, the electrodes 51a and 51b as well as the conductive layers 35a and 35b include UFG-Cu layers, which improves process windows. In some arrangements, the electrodes 51a and 51b do not include UFG-Cu layers, and the conductive layers 35a and 35b include UFG-Cu layers. In this case, the use of UFG-Cu layers can improve process conditions compared to conventional electronic devices.

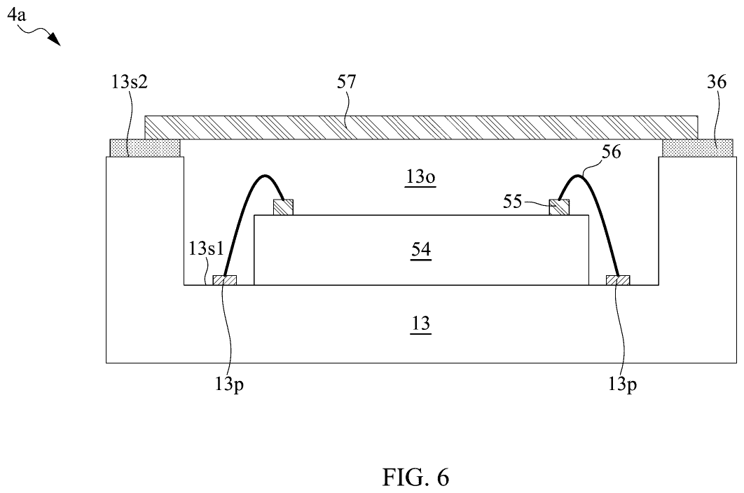

FIG. 6 is a cross-section of an electronic device 4a in accordance with some arrangements of the present disclosure.

In some arrangements, the electronic device 4a may include a carrier 13. The carrier 13 may include a semiconductor substrate, such as silicon, germanium, and other group III-V and group IV materials. In some arrangements, the carrier 13 may be formed as a PCB, FPCB, or other suitable circuit structures. In some arrangements, the carrier 13 may include a lead frame, which may include a patterned trace on its exposed surfaces for electrical connection. In some arrangements, the carrier 13 may include a molding compound, ceramic carrier, or other opaque materials. In some arrangements, the carrier 13 may include a surface 13s1 and a surface 13s2 at different levels (or elevations). The surface 13s1 may be recessed from the surface 13s2. The surfaces 13s1 and 13s2 may define an opening 13o.

In some arrangements, the electronic device 4a may include an electronic component 54. The electronic component 54 may be disposed on the surface 13s1 of the carrier 13. The electronic component 54 may be disposed within the opening 13o. The electronic component 54 may include a micro electro mechanical system (MEMS) die, a microprocessor unit (MPU), a graphics processing unit (GPU), a microcontroller unit (MCU), a radio frequency integrated circuit (RFIC), an application-specific IC (ASIC), a field-programmable gate array (FPGA), high band memory (HBM) die, dynamic random access memory (DRAM) die, static random access memory (SRAM) die, or other integrated circuits (ICs). The electronic component 54 may have a pad 55 and a conductive wire 56 connected between the surface 13s1 of the carrier 13 and the pad 55. The conductive wire 56 may be bonded to a conductive layer 13p on the surface 13s1. The conductive layer 13p may include a UFG-Cu layer. In some arrangements, the grain size of the conductive layer 13p is less than the grain size of the conductive wire 56.

In some arrangements, the electronic device 4a may include a conductive layer 36 (or pad). The conductive layer 36 may be disposed on the surface 13s2 of the carrier 13. In some arrangements, the conductive layer 36 may include a conductive material, such as copper, gold, silver, nickel, titanium, alloys, or other materials. In some arrangements, the conductive layer 36 may include a non-NT-Cu structure. In some arrangements, the conductive layer 36 may include a UFG-Cu layer. In some arrangements, the conductive layer 36 may be formed by, for example, electroplating, electroless plating, or other suitable techniques.

In some arrangements, the electronic device 4a may include a cover 57. The cover 57 may be bonded to or attached to the conductive layer 36. In some arrangements, the cover 57 may include a metallic material, such as copper, gold, silver, nickel, titanium, alloys, or other materials.

In some arrangements, the carrier 13, conductive layer 36, and cover 57 may be configured to create a hermetic space that effectively prevents interference between electronic components. In this arrangement, the conductive layer 36 may have a relatively small roughness. For example, the surface roughness (Ra) of the conductive layer 36 may be equal to 5 nm, 1 nm, 0.5 nm, 0.3 nm, 0.1 nm, or less, and the grain size of the conductive layer 36 may range from 80 nm to about 120 nm. Therefore, the cover 57 may be attached to the conductive layer 36 with a better hermeticity.

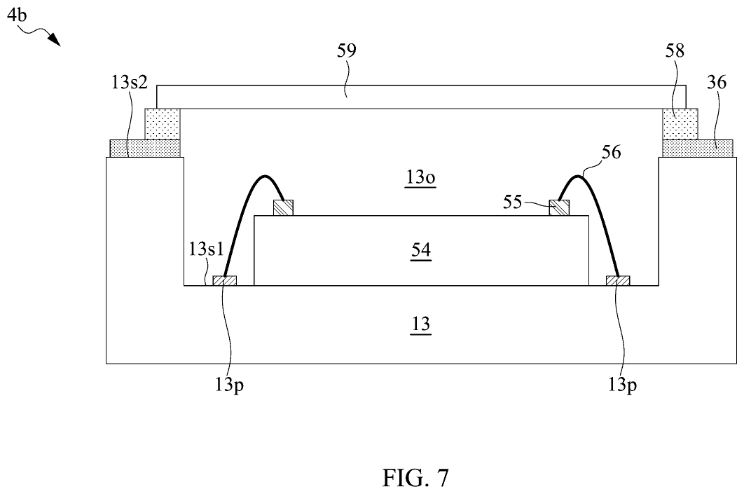

FIG. 7 is a cross-section of an electronic device 4b in accordance with some arrangements of the present disclosure. The electronic device 4b is similar to the electronic device 4a, differing as follows.

In some arrangements, the electronic device 4b may include a spacer 58. The spacer 58 may be configured to adjust the dimension (e.g., depth) of a hermetic space. In some arrangements, the spacer 58 may include conductive material, such as copper, gold, silver, nickel, titanium, alloys, or other materials. In some arrangements, the spacer 58 may include a non-NT-Cu structure. In some arrangements, the spacer 58 may include a UFG-Cu layer. In some arrangements, the spacer 58 may be formed by, for example, electroplating, electroless plating, or other suitable techniques. The spacer 58 and the conductive layer 36 may define a copper-to-copper bonding.

In some arrangements, the electronic device 4b may include a cover 59. In some arrangements, the cover 59 may include a transparent carrier, such as glass or other suitable carriers. In some arrangements, the carrier 13, conductive layer 36, spacer 58, and cover 59 may be configured to create a hermetic space that effectively prevents interference between electronic components. In this arrangement, the conductive layer 36 may have a relatively small roughness. Therefore, the spacer 58 may be attached to the conductive layer 36 with a better hermeticity.

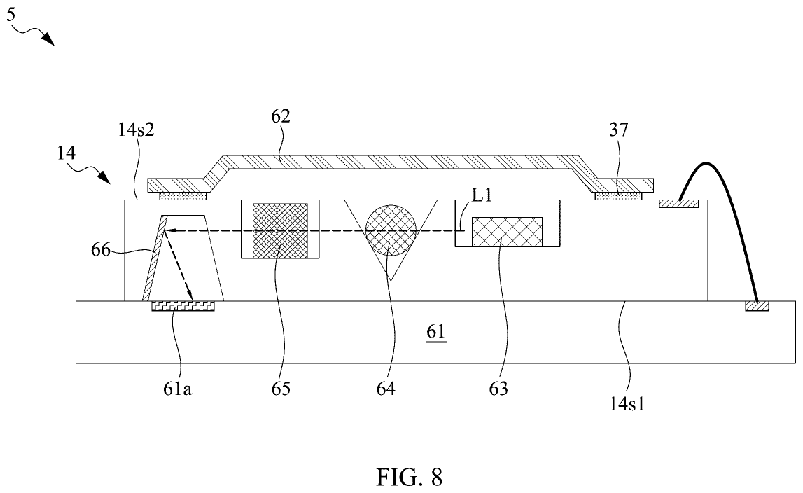

FIG. 8 is a cross-section of an electronic device 5 in accordance with some arrangements of the present disclosure.

In some arrangements, the electronic device 5 may include a carrier 14. The carrier 14 may have a surface 14s1 and a surface 14s2 opposite to the surface 14s1. The carrier 14 may define a plurality of recesses (or cavities) recessed from the surface 14s1 or 14s2. Optical components, such as light emitters, light directors (e.g., lenses), reflectors (e.g., metal planes), may be disposed within the recesses.

In some arrangements, the electronic device 5 may include an optical component 61. In some arrangements, the optical component 61 may include a photonic component, such as a photonic integrated circuit (PIC), which may include waveguide, photodiode, or other suitable elements. The optical component 61 may be optically coupled to the carrier 14. In some arrangements, the optical component 61 may be disposed on the surface 14s1 of the carrier 14.

In some arrangements, the electronic device 5 may include a conductive layer 37. The conductive layer 37 may be disposed on the surface 14s2 of the carrier 14. In some arrangements, the conductive layer 37 may be configured to define a hermetic space. In some arrangements, the conductive layer 37 may include a conductive material, such as copper, gold, silver, nickel, titanium, alloys, or other materials. In some arrangements, the conductive layer 37 may include a non-NT-Cu structure. In some arrangements, the conductive layer 37 may include a UFG-Cu layer. In some arrangements, the conductive layer 37 may be formed by, for example, electroplating, electroless plating, or other suitable techniques.

In some arrangements, the electronic device 5 may include a cover 62. The cover 62 may be bonded to or attached to the conductive layer 37. In some arrangements, the cover 62 may include a metallic material, such as copper, gold, silver, nickel, titanium, alloys, or other materials.

In some arrangements, the electronic device 5 may include a light emitter 63, an optical element 64, an isolator 65, and a reflector 66. The light emitter 63 may be configured to emit a light L1 that passes through the carrier 14, the optical element 64, and the isolator 65. The light L1 may be redirected by the reflector 66 and then incident to an optical receiving region 61a of the optical component 61. The light emitter 63 may include a laser diode, LED, or other light emitters. The optical element 64 may include a lens or other suitable elements. The isolator 65 may be configured to allow the light L1 to be transmitted along a specific direction(s). The reflector 66 may include metallic materials.

In some arrangements, the carrier 14, the conductive layer 37, and the cover 62 may be configured to create a hermetic space that effectively prevents interference between electronic components. In this arrangement, the conductive layer 37 may have a relatively small roughness. Therefore, the cover 62 may be attached to the conductive layer 37 with a better hermeticity.

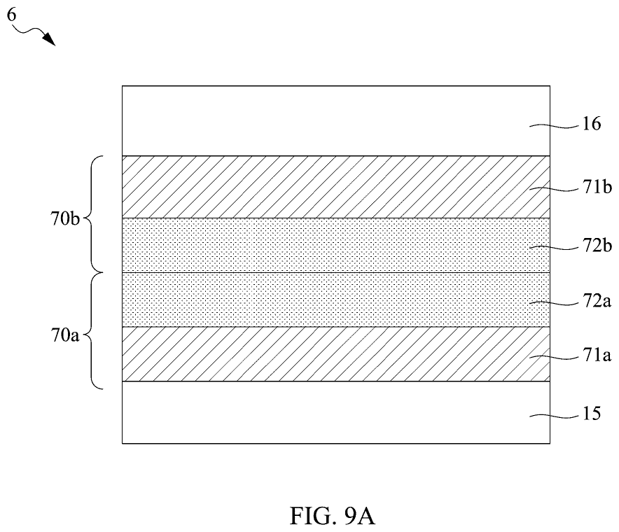

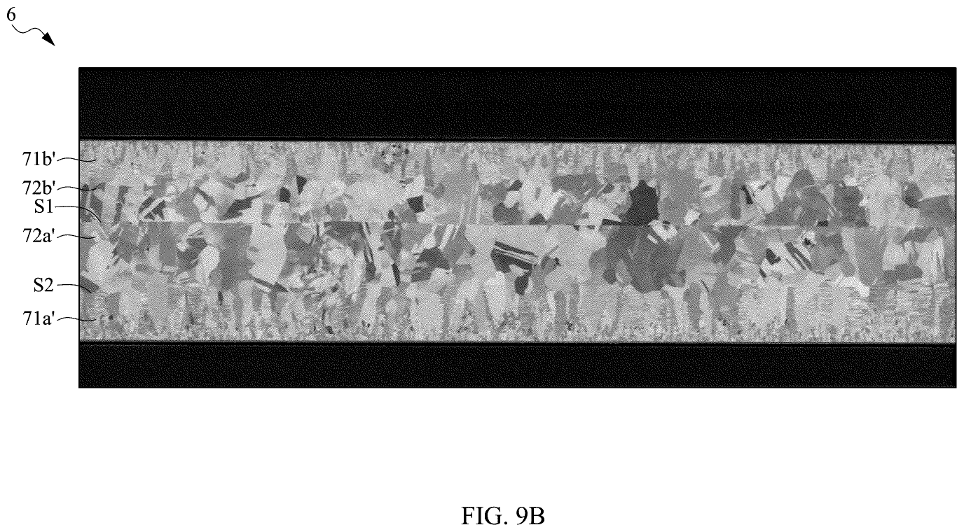

FIG. 9A is a cross-section of an electronic device 6 in accordance with some arrangements of the present disclosure.

In some arrangements, the bonding structure may include a carrier 15 and a carrier 16. Each of the carriers 15 and 16 may include a semiconductor substrate, such as silicon, germanium, and other group III-V and group IV materials. In some arrangements, each of the carriers 15 and 16 may be formed as a PCB, FPCB, or other suitable circuit structures. In some arrangements, each of the carriers 15 and 16 may include a lead frame, which may include a patterned trace on its exposed surfaces for electrical connection. In some arrangements, each of the carriers 15 and 16 may include or be a part of a seed layer.

A bonding structure 70a may be formed on the carrier 15. In some arrangements, the bonding structure 70a may include a conductive layer 71a and a conductive layer 72a. In some arrangements, the conductive layer 71a may include a NT-Cu structure. In some arrangements, the conductive layer 72a may include a UFG-Cu layer. In some arrangements, the grain size of the conductive layer 72a may be less than that of the conductive layer 71a.

A bonding structure 70b may be formed on the carrier 16. In some arrangements, the bonding structure 70b may include a conductive layer 71b and a conductive layer 72b. In some arrangements, the conductive layer 71b may include a NT-Cu structure. In some arrangements, the conductive layer 72b may include a UFG-Cu layer. In some arrangements, the grain size of the conductive layer 72b may be less than that of the conductive layer 71b.

In this arrangement, the bonding structure 70a may be bonded to the bonding structure 70b, thereby forming the electronic device 6. Since the conductive layers 72a and 72b include UFG-Cu layers, the bonding structure 70a may be bonded to the bonding structure 70b with an improved process window.

FIG. 9B illustrates a microstructure of the electronic device 6 after thermal processes are performed, in accordance with some arrangements of the present disclosure.

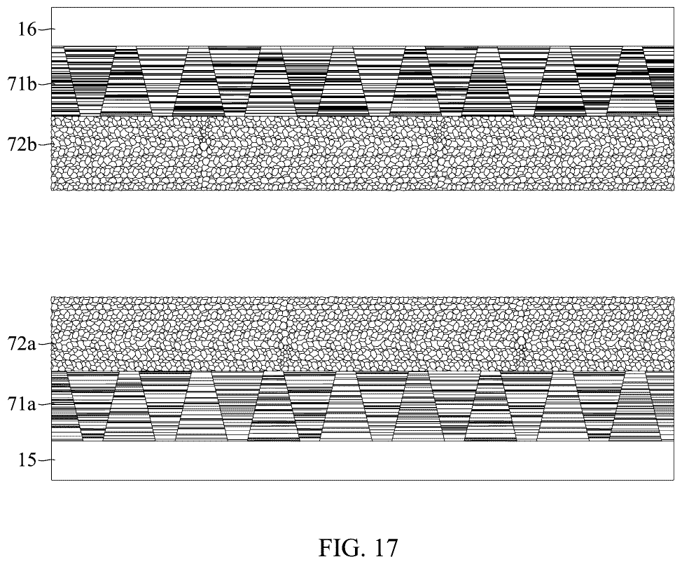

In some arrangements, one or more thermal processes may be performed after the bonding structure 70a is bonded to the bonding structure 70b. In this condition, the grain size of the conductive layers 72a′ and 72b′ may be enlarged. As shown in FIG. 9B, the conductive layers 72a′ and 72b′ may define a boundary S1 therebetween. The conductive layer 71a′ and conductive layer 72a′ may define a boundary S2 therebetween. In some arrangements, the conductive layer 71a′ and 71b′ are made of NT-Cu, whose grain sizes are composed of NT-Cu, whose grains are composed of NT-Cu and relatively stable against temperature changes compared with non-NT-Cu. In this arrangement, after one or more thermal processes are performed, the grain size (or average grain size or D50) of the conductive layer 72a′ (or 72b′) may be substantially equal to or greater than that of the conductive layer 71a′ (or 71b′). The change in grain size of the conductive layers 71a, 71b, 72a, and 72b is illustrated in FIGS. 17-19.

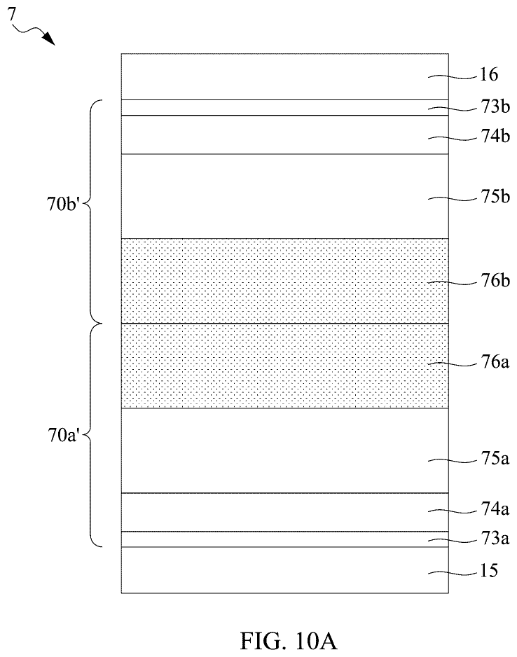

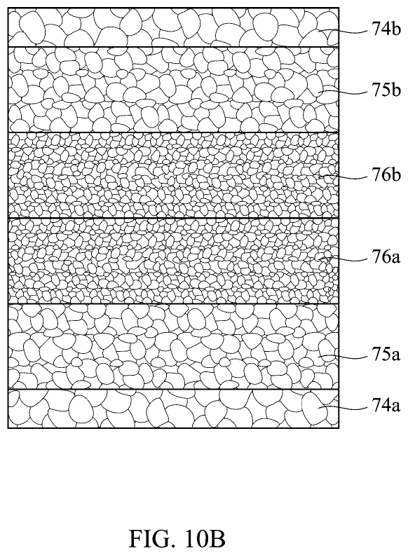

FIGS. 10A and 10B illustrate an electronic device 7 in accordance with some arrangements of the present disclosure. The electronic device 7 is similar to the electronic device 6, differing as follows.

In some arrangements, the bonding structure 7 may include a bonding structure 70a′ and a bonding structure 70b′. The bonding structure 70a′ may include a conductive layer 73a, a conductive layer 74a, a conductive layer 75a, and a conductive layer 76a. The bonding structure 70b′ may include a conductive layer 73b, a conductive layer 74b, a conductive layer 75b, and a conductive layer 76b.

The conductive layers 73a and 73b may function as at least a part of a seed layer. In some arrangements, the conductive layers 73a and 73b may include titanium, tantalum, titanium nitride, or other suitable materials.

The conductive layers 74a and 74b may be formed on the conductive layers 73a and 73b, respectively. In some arrangements, the conductive layers 73a and 73b may include copper with grain size (or average grain size or D50) equal to or greater than 1.5 μm. In some arrangements, the conductive layer 74a may have a thickness greater than that of the conductive layer 73a.

The conductive layers 75a and 75b (or intermediate layers) may be formed on the conductive layers 74a and 74b, respectively. In some arrangements, the conductive layers 75a and 75b may include fine-grain Cu (FG-Cu) layers. In some arrangements, the conductive layers 75a and 75b may include copper with grain size (or average grain size or D50) ranging between about 500 nm and 1.5 μm, between about 500 nm and 1 μm, or between about 500 nm and 800 nm. In some arrangements, the conductive layer 75a may have a thickness greater than that of the conductive layer 74a.

The conductive layers 76a and 76b may be formed on the conductive layers 75a and 75b, respectively. In some arrangements, the conductive layers 76a and 76b may include UFG-Cu layers. In some arrangements, the grain size (or average grain size or D50) of the conductive layers 76a and 76b may be equal to about 300 nm, 150 nm, 100 nm, 50 nm, or less. The conductive layer 76a may be bonded to the conductive layer 76b, thereby forming the electronic device 7. In some arrangements, the conductive layer 76a may have a thickness greater than that of the conductive layer 74a. In some arrangements, the conductive layer 76a may have a thickness substantially equal to or greater than that of the conductive layer 75a.

As shown in FIG. 10B, the grain size (or average grain size or D50) of the conductive layer 76a may be less than that of the conductive layer 75a; the grain size (or average grain size or D50) of the conductive layer 75a may be less than that of the conductive layer 74a.

In this arrangement, the bonding structure 70a′ may be bonded to the bonding structure 70b′ with an improved process window. In this arrangement, the conductive layers 75a and 76a (or conductive layers 75b and 76b) may function as a conductive smoothening layer, which is configured to compensate the roughness of the conductive layer 74a (or conductive layer 74b). In this arrangement, the thickness of the conductive layer 76a (or the sum of the thickness of the conductive layers 75a and 76a) is greater than that of the conductive layer 74a to generate a relatively flat surface at the bonding surface. In other arrangement, the conductive layers 75a and 75b may be omitted. For example, the conductive layer 76a may be directly formed on the conductive layer 74a.

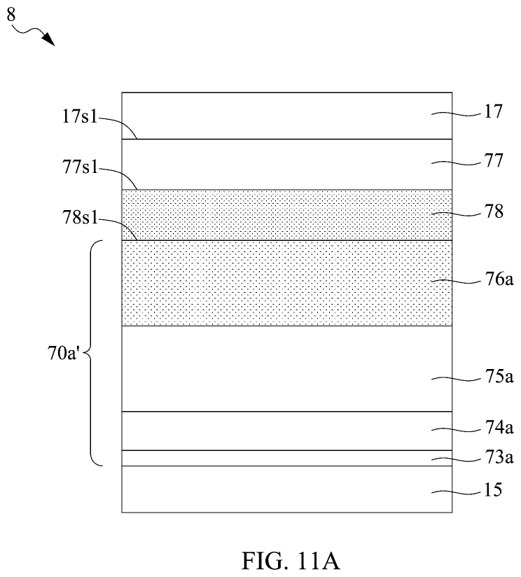

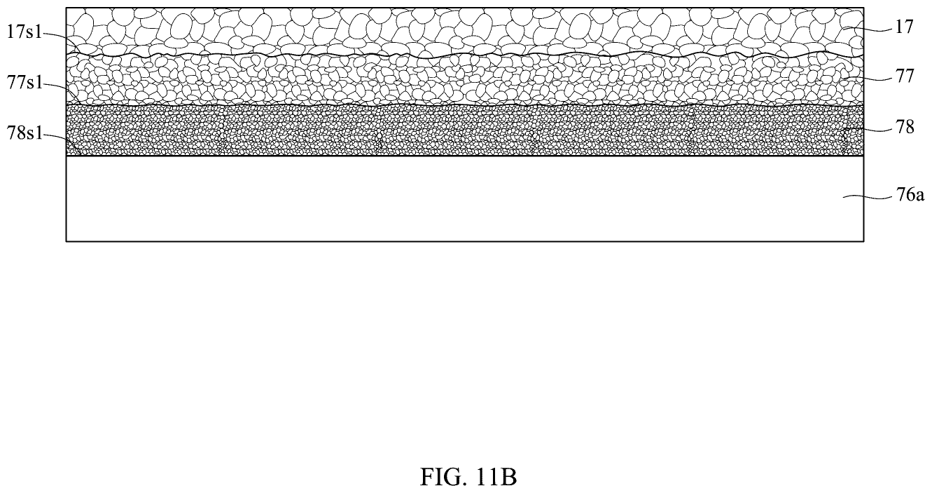

FIG. 11A is a cross-section of an electronic device 8 in accordance with some arrangements of the present disclosure. The electronic device 8 is similar to the bonding structure 7, differing as follows.

In some arrangements, the bonding structure 70a′ may be bonded to a carrier 17. In some arrangements, the carrier 17 may include a lead frame that contains a conductive layer, such as copper, gold, silver, nickel, titanium, alloy, or other suitable materials. In some arrangements, the carrier 17 may include a copper layer with a grain size equal to or greater than 1.5 μm.

A conductive layer 77 may be formed on the surface 17s1 of the carrier 17. In some arrangements, the conductive layer 77 may include an FG-Cu layer.

A conductive layer 78 may be formed on a surface 77s1 of the conductive layer 77. In some arrangements, the conductive layer 78 may include a UFG-Cu layer. The conductive layer 78 may be bonded to the conductive layer 76a, thereby forming the electronic device 8. The conductive layer 78 may have a surface 78s1 functioning as a bonding surface. In some arrangements, the conductive layer 78 may have a thickness greater than that of the conductive layer 77.

In this arrangement, the conductive layers 77, 78, or a combination thereof may function as a conductive smoothening layer, which is configured to compensate the roughness of the surface 17s1 of the carrier 17. As shown in FIG. 11B, the roughness of the surface 78s1 may be less than the roughness of the surface 77s1, and the roughness of the surface 78s1 may be less than the roughness of the surface 17s1, which may facilitate the bonding between the carriers 15 and 17 with an improved process condition. In this arrangement, the bonding surface (e.g., the surface 78s1) may have a smaller surface roughness compared to a comparative example in which no UFG-Cu layer is formed. In this condition, a chemical mechanical polishing process may be omitted.

FIGS. 12 and 13 illustrate partial microstructures at various stages of manufacturing an electronic device 1a, in accordance with some arrangements of the present disclosure.

Referring to FIG. 12, the carrier 11 may be provided. The conductive layer 21 may be formed on the carrier 11. In some arrangements, the conductive layer 21 may be made of NT-Cu. The conductive layer 31 may be formed on the conductive layer 21. For example, the conductive layer 31 may be formed on the upper surface and the lateral surface of the conductive layer 21. The conductive layer 31 may be substantially formed on the conductive layer 21. The conductive layer 31 may be made of a UFG-Cu. In some arrangements, the conductive layer 42 may be made of regular Cu. The conductive layer 42 of the electronic component 40 (not shown in FIG. 12) may be bonded to the conductive layer 31.

Referring to FIG. 13, after the conductive layer 42 is bonded to the conductive layer 31 one or more heating processes may be performed on the electronic device 1a. In some arrangements, no IMCs are formed between the conductive layers 31 and 42 (or conductive layers 31′ and 42′). The grain size of the conductive layer 31 and the conductive layer 42 may be enlarged, and a conductive layer 31′ and a conductive layer 42′ may be defined. The grain size (or average grain size or D50) of the conductive layer 31′ may be greater than that of the conductive layer 31. For example, the grain size of the conductive layer 31′ may range between about 100 nm and 1.5μm, such as 100 nm, 150 nm, 200 nm, 300 nm, 500 nm, 800 nm, 1μm, or 1.5μm, depending on the process conditions of heating processes. The grain size of the conductive layer 42′ may be greater than about 1.5 μm. The grain size (or average grain size or D50) of the conductive layer 31′ may be less than that of the conductive layer 42′. In some arrangements, the change in grain size (or average grain size or D50) of the conductive layer 31′ may exceed the change in grain size of the conductive layer 42′ after one or more heating processes are performed. A conductive layer 21′ may be defined. The NT-Cu is relatively stable against temperature changes compared with non-NT-Cu. In this arrangement, after one or more thermal processes are performed, the grain size (or average grain size or D50) of the conductive layer 21′ may be substantially equal to or greater than that of the conductive layer 21.

FIGS. 14 and 15 illustrate partial microstructures at various stages of manufacturing an electronic device 1a, in accordance with some arrangements of the present disclosure.

Referring to FIG. 14, in this arrangement, the conductive layer 42 may be made of UFG-Cu. Therefore, the conductive layer 42 may be bonded to the conductive layer 31 with a relatively small pressure and temperature. In some arrangements, the temperature used for bonding the conductive layer 42 and the conductive layer 31 may be equal to 200° C., 180° C., 170° C., 160° C., 150° C., 120° C., or less. In some arrangements, the pressure used for bonding the conductive layer 42 and the conductive layer 31 may be equal to 3 MPa, 1 MPa, 0.5 MPa, 0.2 MPa, 0.1 MPa, or less.

Referring to FIG. 15, after the conductive layer 42 is bonded to the conductive layer 31 one or more heating processes may be performed on the electronic device 1a. The grain size of the conductive layer 31 and the conductive layer 42 may be enlarged, and a conductive layer 31′ and a conductive layer 42′ may be defined. In this arrangement, the conductive layers 31 and 42 are made of UFG-Cu. Accordingly, the change in grain size (or average grain size or D50) of the conductive layer 31′ may be substantially equal to the change in grain size of the conductive layer 42′ after one or more heating processes are performed.

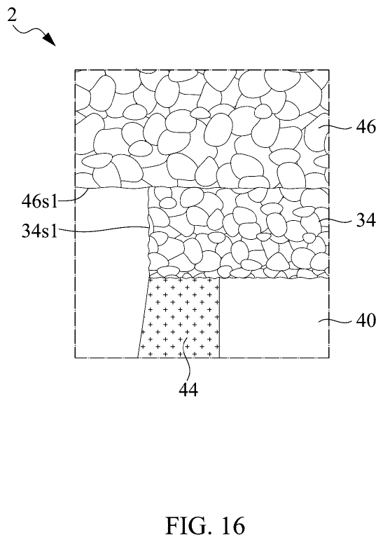

FIG. 16 illustrates a partial microstructure of the electronic device 2 as shown in FIG. 4B, in accordance with some arrangements of the present disclosure.

In some arrangements, the conductive layer 34 may have a surface 34s1 (or lateral surface). The heat dissipating structure 46 may have a surface 46s1 facing the conductive layer 34. The heat dissipating structure 46 may have a grain size greater than that of the conductive layer 34. The surface roughness of the surface 46s1 may be greater than that of the surface 34s1. In some arrangements, the conductive layer 34 is formed after the protection layer 44. Accordingly, the conductive layer 34 may cover the protection layer 44. In other arrangements, the conductive layer 34 may be formed before the protection layer 44, and the protection layer 44 may cover the surface 34s1.

FIGS. 17, 18, and 19 illustrate partial microstructures at various stages of manufacturing an electronic device, in accordance with some arrangements of the present disclosure.

Referring to FIG. 17, the carrier 15 may be provided. The conductive layer 71a may be formed on the carrier 15. The conductive layer 72a may be formed on the conductive layer 71a. The carrier 16 may be provided. The conductive layer 71b may be formed on the carrier 16. The conductive layer 72b may be formed on the conductive layer 71b. In some arrangements, the conductive layers 71a and 71b may be made of NT-Cu structure (or NT-Cu layer), and the conductive layers 72a and 72b may be made of UFG-Cu layer. The grain size (or average grain size or D50) of the conductive layer 72a may be less than that of the conductive layer 71a.

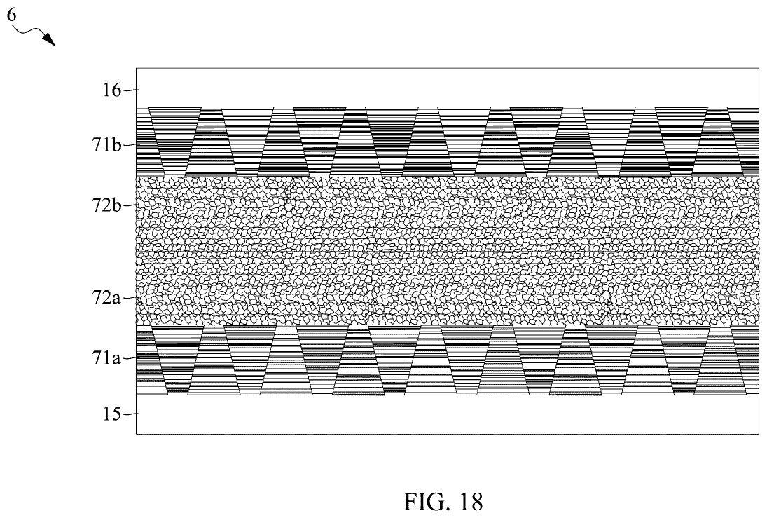

Referring to FIG. 18, the conductive layer 72a may be bonded to the conductive layer 72b. In some arrangements, the temperature used for bonding the conductive layer 72a and the conductive layer 72b may be equal to 160° C., 150° C., 120° C., or less. In some arrangements, the pressure used for bonding the conductive layer 72a and the conductive layer 72b may be equal to 3 MPa, 1 MPa, 0.5 MPa, 0.2 MPa, 0.1 MPa, or less. The electronic device 6 may be produced.

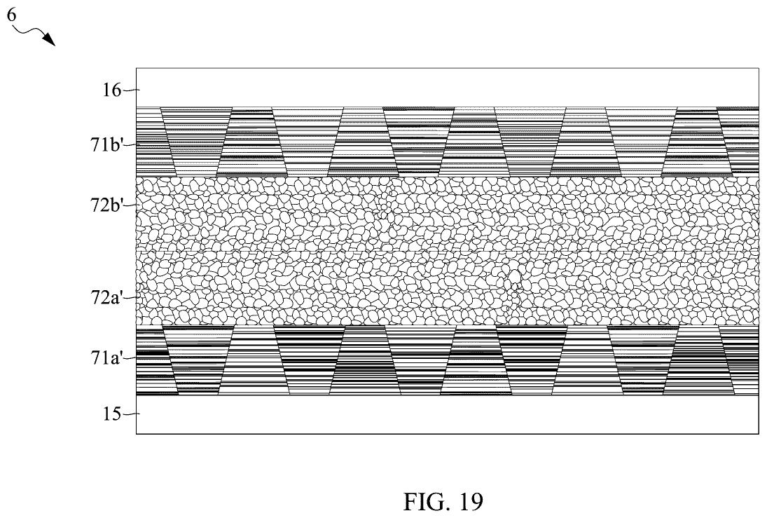

Referring to FIG. 19, one or more heating processes may be performed on the electronic device 6. The grain size of the conductive layers 71a, 71b, 72a, and 72b may be enlarged, and 71a′, 71b′, 72a′, and 72b′ may be defined. In some arrangements, the conductive layer 71a′ and 71b′ are made of NT-Cu, whose grains are composed of NT-Cu and relatively stable against temperature changes compared with non-NT-Cu. In this arrangement, after one or more thermal processes are performed, the grain size (or average grain size or D50) of the conductive layer 72a′ (or 72b′) may be substantially equal to or greater than that of the conductive layer 71a′ (or 71b'). In some arrangements, the change in grain size (or average grain size or D50) of the conductive layer 72a′ (or 72b′) may exceed the change in grain size of the conductive layer 71a′ (or 71b') after one or more heating processes are performed.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some arrangements, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific arrangements thereof, these descriptions and illustrations do not limit the present disclosure. It can be clearly understood by those skilled in the art that various changes may be made, and equivalent components may be substituted within the arrangements without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. An electronic device, comprising:
a carrier comprising a first conductive layer, wherein the first conductive layer comprises a non-nanotwin copper layer and has an average grain size equal to or less than about 150 nm; and
an electronic component comprising a pad electrically connected to the first conductive layer, wherein the pad of the electronic component and the first conductive layer define a copper-to-copper bond.

2. The electronic device of claim 1, wherein an average grain size of the pad is different from the average grain size of the first conductive layer.

3. The electronic device of claim 1, wherein the electronic component has a first surface facing the carrier and a second surface opposite to the first surface, and a thermally conductive layer is disposed on the second surface of the electronic component, and wherein an average grain size of the thermally conductive layer is equal to or less than about 150 nm.

4. The electronic device of claim 3, further comprising:
a heat dissipating structure over the thermally conductive layer, wherein an average grain size of the heat dissipating structure is greater than the average grain size of the thermally conductive layer.

5. The electronic device of claim 4, wherein a surface roughness of the thermally conductive layer is less than a surface roughness of the heat dissipating structure.

6. The electronic device of claim 1, wherein the carrier comprises a second conductive layer spaced apart from the electronic component by the first conductive layer, and the second conductive layer has an average grain size different from the average grain size of the first conductive layer.

7. The electronic device of claim 6, wherein the second conductive layer comprises a nanotwin copper layer.

8. The electronic device of claim 6, wherein the first conductive layer is conformally disposed on the second conductive layer.

9. The electronic device of claim 1, wherein no intermetallic compound is formed between the pad of the electronic component and the first conductive layer of the carrier.

10. An electronic device, comprising:
a carrier;
an electronic component disposed on the carrier, wherein the electronic component has a first surface facing the carrier and a second surface opposite to the first surface;
a first ultra-fine grain copper (UFG-Cu) layer over the second surface of the electronic component; and
a heat dissipating structure on the first UFG-Cu layer.

11. The electronic device of claim 10, wherein the carrier comprises a second UFG-Cu layer connected to the heat dissipating structure.

12. The electronic device of claim 11, wherein the carrier comprises a third UFG-Cu layer connected to the electronic component.

13. The electronic device of claim 12, wherein the carrier comprises a nano-twin Cu layer spaced apart from the heat dissipating structure by the third UFG-Cu layer.

14. The electronic device of claim 10, wherein a surface roughness of the first UFG-Cu layer is less than a surface roughness of the heat dissipating structure.

15. The electronic device of claim 10, further comprising:
a protection layer covering a lateral surface of the electronic component, wherein the first UFG-Cu layer covers the protection layer.

16. A method of manufacturing an electronic device, comprising:
providing a carrier having a first pad;
forming a first ultra-fine grain copper (UFG-Cu) layer over the first pad of the carrier, wherein an average grain size of the first UFG-Cu layer is equal to or less than about 150 nm;
providing a component having a second pad; and
bonding the second pad and the first UFG-Cu layer.

17. The method of claim 16, wherein a temperature during bonding the second pad and the first UFG-Cu layer is equal to or less than about 170° C.

18. The method of claim 16, wherein a pressure during bonding the second pad and the first UFG-Cu layer is equal to or less than about 1 MPa.

19. The method of claim 16, wherein the first pad comprises a nano-twin Cu layer.

20. The method of claim 16, wherein the component has a first surface on which the second pad is formed and a second surface opposite to the first surface, and the method further comprises:
forming a second UFG-Cu layer on a second surface of the component; and
bonding a metallic structure and the second UFG-Cu layer.
